(19) United States
(12) Patent Application Publication
(10) Pub. No.: US 2009/0302716 A1
(43) Pub. Date: Dec. 10, 2009

(54) PIEZOELECTRIC DEVICE

(75) Inventors: Ryoichi OHARA, Kanagawa-ken (JP); Naoko YANASE, Tokyo (JP); Takaaki YASUMOTO, Kanagawa-ken (JP); Shingo MASUKO, Kanagawa-ken (JP); Kenya SANO, Kanagawa-ken (JP)

Correspondence Address: PATTERSON & SHERIDAN, L.L.P., 3040 POST OAK BOULEVARD, SUITE 1500, HOUSTON, TX, 77056, US

(73) Assignee: KABUSHIKI KAISHA TOSHIBA, Tokyo (JP)

(21) Appl. No.: 12/480,480

(22) Filed: Jun. 8, 2009

(30) Foreign Application Priority Data
Jun. 10, 2008 (JP) 2008-151886

(51) Int. Cl. H01L 41/047

(52) U.S. Cl. 310/363

(57) ABSTRACT

A piezoelectric device which is a MEMS device is provided. In the device, the entire silicon layer of the SOI substrate is a p-type region. A plurality of n-type regions are formed in the silicon layer so as to be exposed to the upper surface of the silicon layer and spaced from each other. A piezoelectric film made of AlN is provided on the SOI substrate so as to contact the n-type region, and a conductor film made of aluminum is provided on the piezoelectric film. Thereby, the n-type region functions as a lower electrode and the conductor film functions as an upper electrode.

### CROSS-REFERENCE TO RELATED APPLICATIONS

This application is based upon and claims the benefits of priority from the prior Japanese Patent Application No. 2008-151886, filed on Jun. 10, 2008; the entire contents of which are incorporated herein by reference.

### BACKGROUND OF THE INVENTION

1. Field of the Invention

This invention relates to a piezoelectric device.

2. Background Art

Recently, MEMS (micro electro mechanical system) devices made by semiconductor processes have been rapidly prevailing in various fields. Such devices include sensing devices for sensing mechanical physical quantities, such as an acceleration sensor, gyro sensor, shock sensor, microphone, and pressure sensor; devices for mechanically deforming a microstructure by an electrical signal, such as a switch, variable capacitance device, motor, actuator, and movable mirror; and devices based on resonance of a microstructure, such as a resonator and a filter including a combination of resonators.

While MEMS technology has thus realized devices having diverse functions, the operating principle of these devices is also based on diverse physical phenomena. For example, a capacitor can detect the displacement of the electrode as a capacitance change and convert it into an electrical signal. On the other hand, by applying a voltage to the capacitor, an electrostatic force can be produced between the electrodes to generate mechanical displacement and vibration. Such interconversion between the electrical physical quantity and the mechanical physical quantity can be realized by using a magnetic field, such as induced electromotive force and Lorentz force, or by using the piezoelectric effect or the inverse piezoelectric effect. With regard to sensing, the piezoresistance effect of a semiconductor can be used to sense a strain as a resistance change, and heat conduction can be used to sense the motion of gas.

Among such various MEMS technologies, one of those finding widespread applications is a sensor/actuator based on a capacitor. One reason for this is that it can be constructed simply by opposing two electrode plates across an air layer, and hence there is no need to introduce novel materials into the manufacturing process. In addition, advantageously, the sensitivity and the generated force can be controlled by the gap between the electrode plates and the DC bias applied between the electrode plates, achieving a high design freedom. On the other hand, as for drawbacks, use of a capacitor across an air layer increases the device impedance, the electrostatic force is only attractive and additionally nonlinear, and a voltage booster circuit for generating a DC bias is required. Another drawback is that in a microphone and pressure sensor, two electrode plates are required as membranes, which complicate the structure.

In contrast, a MEMS device based on the piezoelectric effect or the inverse piezoelectric effect can solve all the problems with the above MEMS devices based on the electrostatic force. The MEMS device based on the piezoelectric effect or the inverse piezoelectric effect is realized by bonding two electrodes to a piezoelectric film. This MEMS device has low impedance because of the high dielectric constant of the piezoelectric, can generate force in both of the positive and negative direction, and requires no DC bias for operation.

However, fabrication of such a MEMS device requires introducing a novel piezoelectric into the silicon process. Typical piezoelectrics include ferroelectrics, such as aluminum nitride (AlN), zinc oxide (ZnO), and PZT (PbZrₓTi₁₋ₓO₃, lead zirconate titanate). Among them, AlN is highly consistent with LSI processes. In order for such a piezoelectric to exhibit high piezoelectricity, the piezoelectric film needs to have a highly oriented crystal structure. To this end, selection of a lower electrode serving as a foundation of the piezoelectric film, and treatment before processing the piezoelectric film are important points.

In the case where the lower electrode is formed from metal, for example, molybdenum (Mo), tungsten (W), or aluminum (Al), to enhance the orientation of the piezoelectric film formed on this lower electrode, it is necessary to form a foundation layer for the lower electrode. Furthermore, it is difficult to orient AlN after processing the lower electrode. Moreover, if the end portion of the lower electrode is steeply tapered, cracks are likely to occur in the piezoelectric film formed thereon. Furthermore, because the piezoelectric film formed is not flat, unfortunately, an upper electrode or interconnect formed thereon may include a step disconnection, or an etching liquid for processing the upper electrode or interconnect may dissolve the lower electrode.

In a method proposed to solve these problems, the lower electrode is formed from a semiconductor material such as silicon doped with impurities, instead of a metal material (see, e.g., Antti Jaakkola, et al., “Piezotransduced Single-Crystal Silicon BAW Resonators”, IEDM 1989 p. 880-883). In this method, the highly flat surface of a silicon substrate can be used as a foundation to grow an AlN film. Hence, a highly oriented piezoelectric film can be formed more easily than in the case of growing an AlN film on the lower electrode made of a metal material.

However, in this method, in the case where it is necessary to form a plurality of lower electrodes with electrical insulation from each other, the silicon layer between the lower electrodes needs to be removed by etching. If the silicon layer is removed, the interconnect cannot be routed thereon, and the space previously occupied by the silicon layer needs to be filled with some insulating material. However, such processing in the membrane produces a junction of heterogeneous materials in the thin membrane. Hence, cracks are likely to occur due to stress concentration, decreasing the mechanical strength of the structure.

### SUMMARY OF THE INVENTION

According to an aspect of the invention, there is provided a piezoelectric device including: a silicon substrate with a first-conductivity-type region formed in at least part of an upper portion thereof; a second-conductivity-type region formed in the first-conductivity-type region and exposed to an upper surface of the silicon substrate; a piezoelectric film provided on the silicon substrate, being in contact with the second-conductivity-type region, and made of a piezoelectric; and a conductor film provided on the piezoelectric film and made of a conductive material.

### BRIEF DESCRIPTION OF THE DRAWINGS

FIG. 1 is a cross-sectional view illustrating a piezoelectric device according to a first embodiment of the invention;

FIG. 2 is a schematic cross-sectional view illustrating the expansion/contraction of a piezoelectric film with both ends or the outer peripheral edge of the membrane being fixed;

FIG. 3 is a cross-sectional view illustrating a piezoelectric device according to a first example of the first embodiment;

FIG. 4 is a cross-sectional view illustrating a piezoelectric device according to a second example of the first embodiment;

FIG. 5 is a schematic cross-sectional view illustrating a piezoelectric device according to a third example of the first embodiment;

FIG. 6 is an equivalent circuit diagram of the piezoelectric device according to the third example of the first embodiment;

FIGS. 7A to 7C are plan views illustrating the piezoelectric device according to the third example of the first embodiment, where FIG. 7A shows an SOI substrate provided with a lower electrode, FIG. 7B shows a piezoelectric film, and FIG. 7C shows an upper electrode;

FIGS. 8A to 8C illustrate how the partition number of the capacitance is related to the generated voltage, capacitance, and charge, where FIG. 8A shows the case without partitioning the capacitance, FIG. 8B shows the case of bisecting the capacitance, and FIG. 8C shows the case of n-secting the capacitance;

FIGS. 9A to 9C are plan views illustrating a piezoelectric device according to the fourth example of the first embodiment, where FIG. 9A shows an SOI substrate provided with a lower electrode, FIG. 9B shows a piezoelectric film, and FIG. 9C shows an upper electrode;

FIG. 10 is an equivalent circuit diagram of the piezoelectric device according to the fourth example of the first embodiment;

FIGS. 11A to 11C are plan views illustrating a piezoelectric device according to a fifth example of the first embodiment, where FIG. 11A shows an SOI substrate provided with a lower electrode, FIG. 11B shows a piezoelectric film, and FIG. 11C shows an upper electrode;

FIG. 12 is an equivalent circuit diagram of a piezoelectric device according to the fifth example of the first embodiment;

FIG. 13 is a plan view illustrating the piezoelectric device according to a sixth example of the first embodiment;

FIG. 14 is the equivalent circuit diagram of the piezoelectric device according to the sixth example of the first embodiment;

FIGS. 15A to 15C are schematic plan views illustrating variations of the membrane shape in the first embodiment;

FIG. 16 is a cross-sectional views illustrating a piezoelectric device according to a second embodiment of the invention;

FIG. 17 is a plan view illustrating an angular velocity sensor according to an example of the second embodiment; and

FIGS. 18A to 18C are plan views illustrating the operation of the angular velocity sensor according to the example of the second embodiment.

### DETAILED DESCRIPTION OF THE INVENTION

Embodiments of the invention will be described with reference to the drawings.

At the outset, a first embodiment of the invention is described.

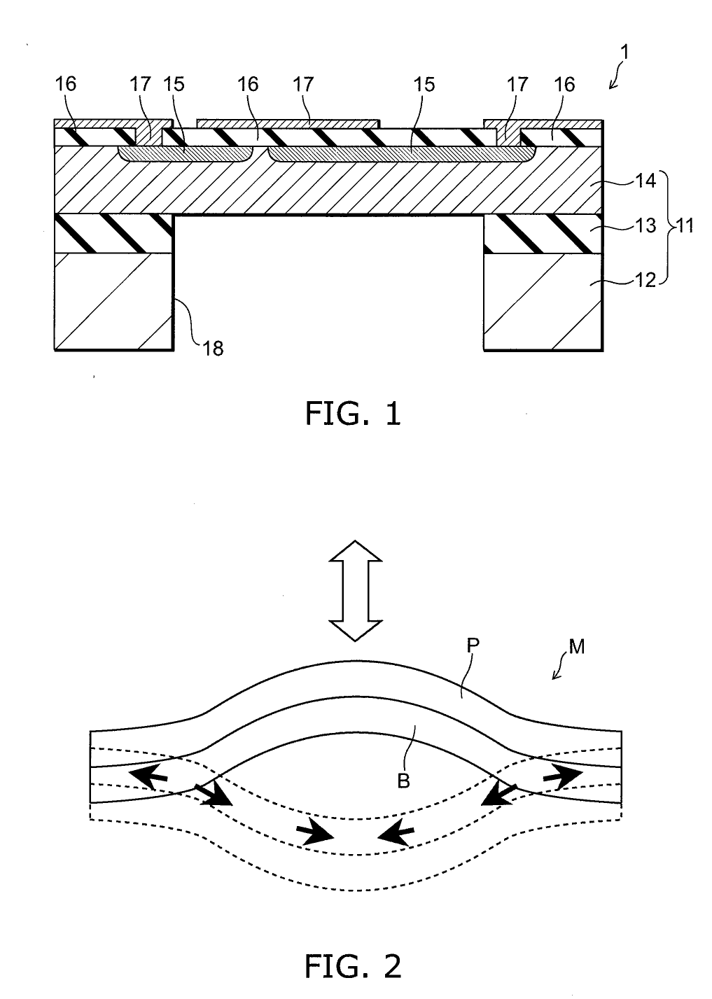

FIG. 1 is a cross-sectional view illustrating a piezoelectric device according to this embodiment.

The piezoelectric device 1 according to this embodiment is a MEMS device fabricated using an SOI (silicon on insulator) substrate, specifically a microphone.

As shown in FIG. 1, the piezoelectric device 1 includes an SOI substrate 11 as a silicon substrate. The SOI substrate 11 includes a support matrix 12 made of silicon (Si), a BOX layer 13 (insulating layer) made of silicon oxide (SiO₂) is provided on the support matrix 12, and a silicon layer 14 made of single crystal silicon is provided on the BOX layer 13. That is, the SOI substrate 11 has a three-layer structure composed of the support matrix 12, the BOX layer 13, and the silicon layer 14, which are bonded to each other. The silicon layer 14 is doped with impurities and given p-type conductivity. That is, the silicon layer 14 constituting the upper portion of the SOI substrate 11 is entirely a p-type region (first-conductivity-type region). The specific resistance of the silicon layer 14 is illustratively 10 Ω·cm, preferably 100 Ω·cm or more, and more preferably 1 kΩ·cm or more. The silicon layer 14 has a thickness of e.g. approximately 0.1 to 5.0 μm.

An n-type region 15 (second-conductivity-type region) having n-type conductivity is formed in part of the upper portion of the silicon layer 14. That is, the n-type region 15 is embedded in the silicon layer 14. Furthermore, the n-type region 15 is exposed to the upper surface of the SOI substrate 11. As described later, the n-type region 15 functions as a lower electrode of the piezoelectric device 1. The silicon layer 14 includes a plurality of n-type regions 15 spaced from each other. The n-type region 15 has a thickness of e.g. approximately 1 μm, contains phosphorus (P) as impurity at a concentration of e.g. 1×10¹⁹ cm⁻³. The impurity concentration in the silicon layer 14 is lower than the impurity concentration in the n-type region 15, that is, the phosphorus concentration therein.

Furthermore, a piezoelectric film 16 made of a piezoelectric, such as aluminum nitride (AlN), is provided on the SOI substrate 11. The piezoelectric film 16 has a thickness of e.g. 1.0 μm. The lower surface of the piezoelectric film 16 is in contact with the upper surface of the silicon layer 14, particularly in contact with the upper surface of the n-type region 15. The piezoelectric film 16 is patterned into a plurality of regions spaced from each other.

Furthermore, a conductor film 17 made of a conductive material, such as a metal or alloy, e.g. aluminum (Al), is provided on the SOI substrate 11. The conductor film 17 is patterned into a plurality of regions spaced from each other. The conductor film 17 is thicker than the piezoelectric film 16 and covers part of the piezoelectric film 16. The conductor film 17 is placed on the piezoelectric film 16 and between the regions of the piezoelectric film 16, and is in contact with the n-type region 15 and the piezoelectric film 16. As described later, the conductor film 17 functions as an upper electrode of the piezoelectric device 1.

On the other hand, the support matrix 12 and the BOX layer 13 of the SOI substrate 11 are removed in the central region of the piezoelectric device 1 to form an opening 18 which opens downward. In other words, the insulating layer 13 is provided only at the end portion of the immediately underlying region of the silicon layer 14, and the support matrix 12 is provided only immediately below the BOX layer 13. Thus, the central portion of the silicon layer 14, that is, the portion located immediately above the opening 18 and not supported by the BOX layer 13 and the support matrix 12, is configured as a semi-free-standing film, allowing deformation and vibration in a certain range. Consequently, the central portion of the silicon layer 14 serves as a base film of the membrane of the piezoelectric device 1. The support matrix 12 and the BOX layer 13 are bonded to the end portion of the silicon layer 14 and constitute a support portion for vibratile supporting the central portion of the silicon layer 14.

Furthermore, a through hole (not shown) communicating with the opening 18 is formed in the central portion of the silicon layer 14. This through hole functions as an air vent when the piezoelectric device 1 is fixed to another substrate (not shown) such as a printed circuit board and the opening 18 is sealed.

The summary of the foregoing is as follows. In the piezoelectric device, the SOI substrate 11 with the support matrix 12, the BOX layer 13, and the silicon layer 14 stacked therein in upward order is provided as a substrate. The cavity (opening 18) is formed in the central portion of the SOI substrate 11 from the lower surface end, and the support matrix 12 and the BOX layer 13 are removed. Consequently, only the central portion of the silicon layer 14 exists immediately above the cavity (opening 18), serving as the base film of the membrane. In the later-described examples of the embodiment, the central portion (base film) is referred to as a “silicon film.” The n-type region 15 is selectively formed in the base film, serving as the lower electrode. On the other hand, the piezoelectric film 16 is provided on the base film, and the conductor film 17 is selectively provided thereon, the conductor film 17 serving as the upper electrode. The base film (the central portion of the silicon layer 14), the piezoelectric film 16, and the conductor film 17 (upper electrode) constitute the membrane. Namely, in the piezoelectric device 1 according to this embodiment, the lower electrode of the capacitance (n-type region 15) is formed in the base film. As viewed from above, the positional relation of the piezoelectric film 16 and the base film is arbitrary. In the present embodiment, the piezoelectric film 16 covers all of the base film. However, the piezoelectric film may cover only part of the base film as described in the examples below.

Next, a method for manufacturing the piezoelectric device 1 according to this embodiment is described.

First, an SOI substrate 11 is prepared. In advance, the silicon layer 14 of the SOI substrate 11 is doped with impurities and is entirely a p-type region. Next, a resist film (not shown) is formed on the SOI substrate 11 and used as a mask to perform ion implantation with phosphorus (P). The condition of this ion implantation is illustratively an acceleration voltage of 250 kV and a dose amount of 1×10¹⁵ cm⁻². Subsequently, the resist film is stripped off. Next, annealing is performed at a temperature of e.g. 1100° C. to diffuse and activate the implanted phosphorus ions. This results in a phosphorus concentration of 1×10¹⁹ cm⁻³ in the region of the silicon layer 14 from the upper surface to a depth of approximately 1 μm. Thus, a plurality of n-type regions 15 are formed in part of the upper portion of the silicon layer 14.

Next, by reactive magnetron sputtering, aluminum nitride (AlN) is deposited on the SOI substrate 11 to a thickness of e.g. 1.0 μm to form an AlN film. Here, the sputter gas is illustratively a mixed gas of argon (Ar) and nitrogen (N₂), and the target power is illustratively 5 kW. Next, this AlN film is patterned by reactive ion etching (RIE) using a chlorine-based gas. This results in a piezoelectric film 16 made of AlN and processed into a prescribed pattern.

Consecutively, by magnetron sputtering, aluminum (Al) is deposited to a thickness of e.g. 500 nm to form an Al film. Next, this Al film is patterned by RIE using a chlorine-based gas. This results in a conductor film 17 made of Al and processed into a prescribed pattern. It is noted that this patterning may be performed by wet etching with liquid chemicals instead of RIE.

Next, RIE using a chlorine-based gas or fluorine-based gas is performed on the silicon layer 14 to form a through hole reaching the BOX layer 13. Next, D-RIE (deep RIE) is performed from the lower surface side of the SOI substrate 11 to remove the support matrix 12 from the central region of the SOI substrate 11 to form an opening. At this point, the BOX layer 13 is exposed to the bottom of the opening. Next, a BHF (buffered hydrofluoric acid) solution is used to etch away the BOX layer 13 to form an opening 18 reaching the silicon layer 14. At this time, the opening 18 communicates with the through hole formed in the silicon layer 14, and the upper surface side and the lower surface side of the piezoelectric device 1 communicate with each other. Thus, the piezoelectric device 1 is manufactured.

Next, the operation of the piezoelectric device 1 according to this embodiment is described.

In the piezoelectric device 1, the n-type region 15 functions as a lower electrode. Furthermore, the conductor film 17 functions as an upper electrode. Thus, a capacitance C is formed in the piezoelectric film 16 placed between the n-type region 15 (lower electrode) and the conductor film 17 (upper electrode).

In response to propagation of an acoustic wave from outside the piezoelectric device 1, the membrane undergoes flexural vibration. This flexural vibration causes the piezoelectric film 16 to horizontally expand and contract, generating a potential difference between the n-type region 15 (lower electrode) and the conductor film 17 (upper electrode). By detecting this potential difference, the acoustic wave can be sensed. That is, the piezoelectric element composed of the n-type region 15, the piezoelectric film 16, and the conductor film 17 functions as a sensor element for sensing the deformation of the silicon layer 14.

Next, the effect of this embodiment is described.

In this embodiment, the n-type region 15 serving as a lower electrode is formed as part of the silicon layer 14 made of single crystal silicon. Hence, the AlN film deposited on the n-type region 15 can be highly oriented. Thus, a highly oriented piezoelectric film 16 can be obtained, and its piezoelectricity can be fully exhibited.

Furthermore, in this embodiment, in contrast to the case where the lower electrode is formed from a metal material, there is no need to form a foundation layer for the lower electrode, which simplifies the manufacturing process.

Moreover, because the n-type region 15 is formed inside the silicon layer 14, the presence of the n-type region 15 does not impair the flatness of the upper surface of the silicon layer 14. Hence, the piezoelectric film 16 can be formed flat and is resistant to cracking and the like. Furthermore, step disconnections and the like are less likely to occur in the conductor film 17 formed on the piezoelectric film 16.

Furthermore, different potentials are applied to a plurality of n-type regions 15, and the p-type silicon layer 14 is interposed between the n-type regions 15. Hence, two or more pn interfaces are necessarily produced between the n-type regions 15, and one of them is reverse biased. As a result, the n-type regions 15 are electrically separated from each other and function as independent lower electrodes. Thus, there is no need to remove the portion of the silicon layer 14 between the n-type regions 15 by etching or the like, and hence there is no need to fill the removed portion with an insulating material. Consequently, the strength of the membrane can be ensured.

Furthermore, a depletion layer extends from the reverse biased pn interface between the n-type regions 15. Here, the impurity concentration in the silicon layer 14 is lower than the impurity concentration in the n-type region 15. Hence, the depletion layer extends longer in the silicon layer 14, and the thickness of the entire depletion layer increases. For example, the depletion layer reaches the lower surface of the silicon layer 14, and the thickness of the depletion layer becomes equal to the thickness of the silicon layer 14. Consequently, the parasitic capacitance produced in the silicon layer 14 can be reduced.

The piezoelectric device 1 according to this embodiment, that is, the piezoelectric MEMS microphone, was actually manufactured, and its characteristics were measured. First, the sound pressure sensitivity for an acoustic wave with a frequency of 1 kHz was −40 dB. Furthermore, the frequency dependence of impedance was characterized using an impedance analyzer. The resonance coupling coefficient for the lowest-order flexural vibration was nearly equal to the theoretical value, and it was confirmed that AlN exhibits good piezoelectricity. Furthermore, 1000 prototypes of the piezoelectric device were manufactured, all free from defects due to structural factors such as breaking and cracking in the membrane.

Thus, this embodiment can realize a piezoelectric device having high mechanical strength with the piezoelectric film highly oriented.

In this embodiment, for example, the silicon layer 14 has p-type conductivity, and the lower electrode (n-type region 15) has n-type conductivity. However, these conductivity types may be reversed. Furthermore, the impurity concentration in the silicon layer 14 is preferably as low as possible. Hence, the silicon layer 14 may be a nearly intrinsic semiconductor unless it assumes the same conductivity type as the n-type regions 15 and connects them to each other. Furthermore, in this embodiment, the piezoelectric film 16 is illustratively formed from aluminum nitride (AlN). However, the piezoelectric forming the piezoelectric film 16 is not limited to AlN, but may be zinc oxide (ZnO) or lead zirconate titanate (PZT), for example. These notices also apply to the second embodiment described later.

Next, examples of the first embodiment are described.

In the first embodiment, the voltage associated with the flexural vibration of the piezoelectric film is detected by the upper electrode and the lower electrode sandwiching the piezoelectric film. The electrode layout of the upper electrode and the lower electrode enabling such detection has numerous variations, but there are some restrictions depending on the type of the device. In the following, these restrictions are described.

FIG. 2 is a schematic cross-sectional view illustrating the expansion/contraction of a piezoelectric film with both ends or the outer peripheral edge of the membrane being fixed.

As shown in FIG. 2, suppose that the base film B of the membrane M is shaped like a fixed-fixed beam with both ends connected to a support portion, or a disc with the outer peripheral portion connected to a support portion, and a piezoelectric film P is formed on the base film B.

In this case, when a pressure is applied to the membrane M from above and the membrane M bends convex downward, the piezoelectric film P horizontally contracts at the center of the membrane, but horizontally expands at the periphery of the membrane. Hence, at the center and the periphery of the membrane, the direction of polarization generated vertically in the piezoelectric film is opposite to each other, and the direction of voltage generated between the upper and lower surface is also opposite to each other. Thus, if the lower electrode, the piezoelectric film, and the upper electrode are formed on the entire surface of the membrane, the voltage generated at the center of the membrane and the voltage generated at the periphery thereof cancel out, producing little voltage signal.

Example electrode layouts that can avoid this problem are described in the following first to third example.

At the outset, a first example is described.

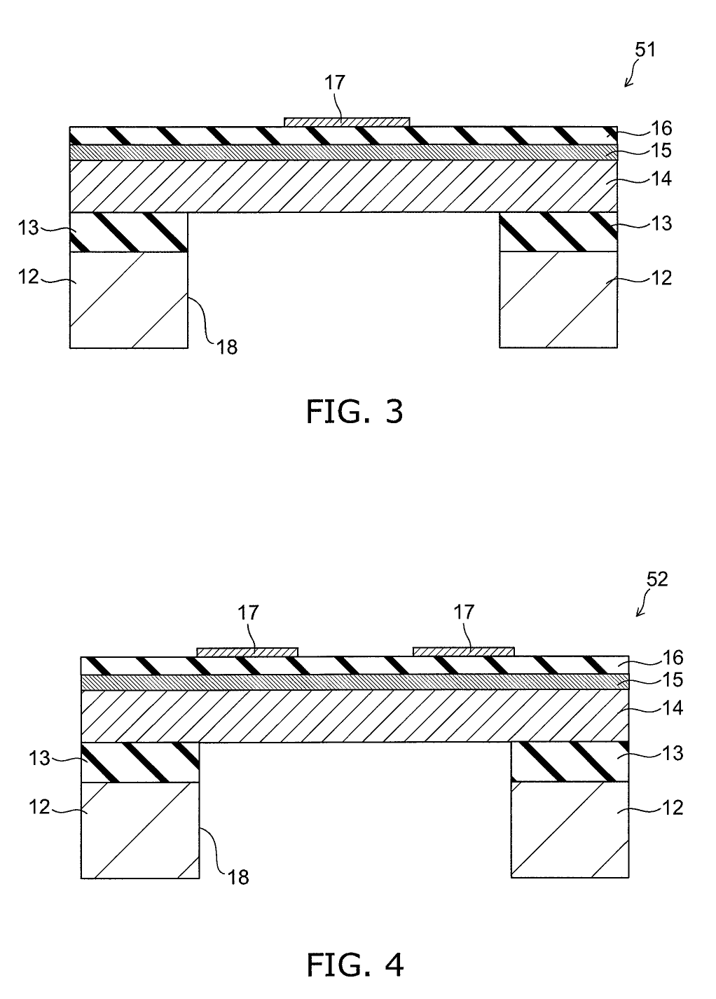

FIG. 3 is a cross-sectional view illustrating a piezoelectric device according to the first example.

As shown in FIG. 3, in the piezoelectric device 51 according to this example, the conductor film 17 serving as an upper electrode is provided only at the center of the membrane. Thus, only the polarization voltage generated at the center of the membrane can be detected. It is noted that an extraction interconnect (not shown) for connecting the conductor film 17 to the outside is formed on the piezoelectric film 16. Here, it is preferable to avoid forming the n-type region 15 immediately below this extraction interconnect. This can reduce the parasitic capacitance between the extraction interconnect and the n-type region 15 and suppress the polarization voltage generated by this parasitic capacitance.

Next, a second example is described.

FIG. 4 is a cross-sectional view illustrating a piezoelectric device according to the second example.

As shown in FIG. 4, in the piezoelectric device 52 according to this example, the conductor film 17 serving as an upper electrode is provided only at the periphery of the membrane. Thus, only the polarization voltage generated at the periphery of the membrane can be detected. Also in this case, like the above first example, it is preferable to avoid forming the n-type region 15 immediately below the extraction interconnect (not shown) connected to the conductor film 17.

Next, a third example is described.

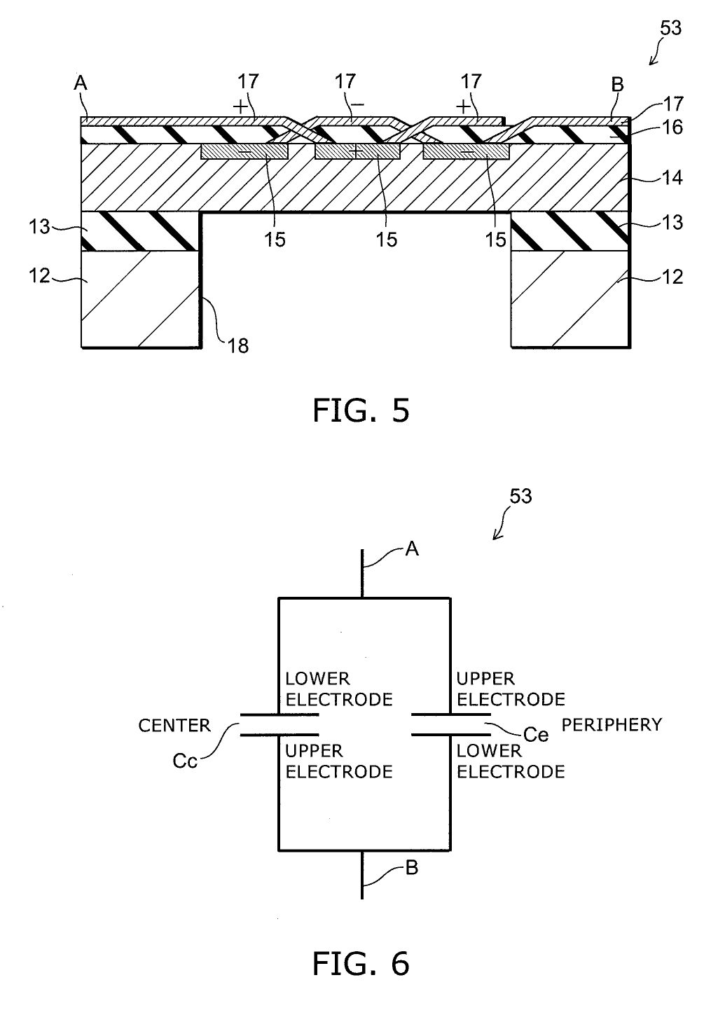

FIG. 5 is a schematic cross-sectional view illustrating a piezoelectric device according to the third example.

FIG. 6 is an equivalent circuit diagram of the piezoelectric device according to the third example.

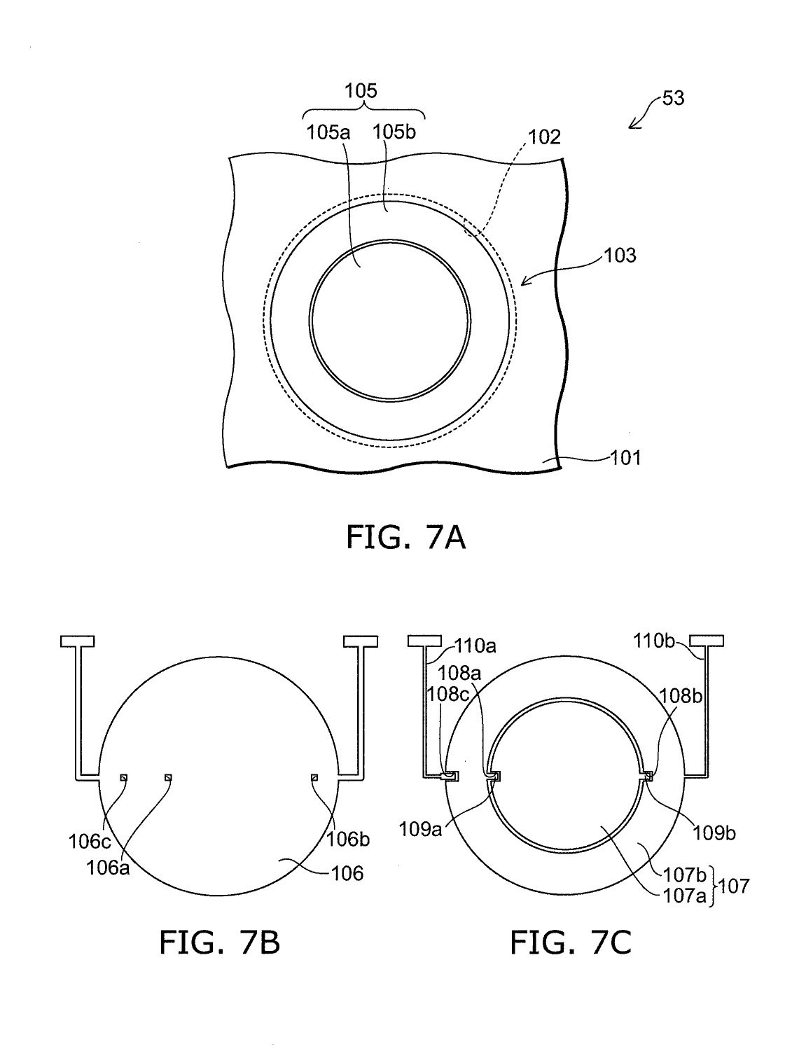

FIGS. 7A to 7C are plan views illustrating the piezoelectric device according to the third example, where FIG. 7A shows an SOI substrate provided with a lower electrode, FIG. 7B shows a piezoelectric film, and FIG. 7C shows an upper electrode.

As shown in FIG. 5, the piezoelectric device 53 according to this example includes a pair of extraction interconnects. One extraction interconnect A is connected to the upper electrode at the periphery and the lower electrode at the center, and the other extraction interconnect B is connected to the lower electrode at the periphery and the upper electrode at the center. Thus, as shown in FIG. 6, in the equivalent circuit of the piezoelectric device 53, a capacitance Cc formed at the center of the membrane and a capacitance Ce formed at the periphery thereof are connected in parallel.

Specifically, as shown in FIG. 7A, the piezoelectric device 53 includes a silicon substrate 101. The silicon substrate 101 may be entirely made of silicon, or may be an SOI substrate as in the first embodiment. In the silicon substrate 101, a circular cavity 102 is formed from the backside. The cavity 102 does not reach the upper surface of the silicon substrate 101. The portion of the silicon substrate 101 located immediately above the cavity 102 constitutes a silicon film 103 serving as a base film of the membrane.

The upper portion of the silicon film 103 is doped with donor to form an n-type region 105 serving as a lower electrode. As viewed from above, that is, in the direction perpendicular to the upper surface of the silicon substrate 101, the n-type region 105 is divided into a circular central portion 105a formed at the center of the silicon film 103 and an annular peripheral portion 105b formed at the periphery. These portions are spaced from each other, and the peripheral portion 105b surrounds the central portion 105a. The substrate 101 around the central portion 105a and the peripheral portion 105b is a p-type region.

As shown in FIG. 7B, a circular piezoelectric film 106 slightly larger than the n-type region 105 is provided on the n-type region 105 so as to cover the n-type region 105. The piezoelectric film 106 is a single continuous film and includes connection vias 106a, 106b, and 106c.

As shown in FIG. 7C, a conductor film 107 is formed on the piezoelectric film 106 and serves as an upper electrode. The silicon film 103, the piezoelectric film 106, and the conductor film 107 constitute the membrane. Like the n-type region 105 (lower electrode), the conductor film 107 is also divided into a circular central portion 107a and an annular peripheral portion 107b. The central portion 107a of the conductor film 107 (upper electrode) is placed immediately above the central portion 105a of the n-type region 105 (lower electrode), and the peripheral portion 107b is placed immediately above the peripheral portion 105b. Thus, a capacitance Cc is formed at the center of the membrane, where the central portion 105a of the n-type region 105 serves as a lower electrode and the central portion 107a of the conductor film 107 serves as an upper electrode, and a capacitance Ce is formed at the periphery of the membrane, where the peripheral portion 105b of the n-type region 105 serves as a lower electrode and the peripheral portion 107b of the conductor film 107 serves as an upper electrode.

One notch 108a is formed at the outer periphery of the central portion 107a, and an extension 109a is provided at a portion of the inner periphery of the peripheral portion 107b opposed to the notch 108a so that the extension 109a enters the notch 108a. Furthermore, a notch 108b is formed at the inner periphery of the peripheral portion 107b, and an extension 109b is provided at a portion of the central portion 107a opposed to the notch 108b. Furthermore, a notch 108c is formed at the outer periphery of the peripheral portion 107b. For example, the notches 108c, 108a, 108b are arranged in a line in this order. The connection vias 106a, 106b, and 106c are placed immediately below the notches 108a, 108b, and 108c, respectively.

Furthermore, the piezoelectric device 53 includes a pair of extraction interconnects 110a and 110b. The extraction interconnects 110a and 110b are formed by patterning the same metal film as the conductor film 107. Furthermore, the piezoelectric film 106 is provided immediately below the extraction interconnects 110a and 110b, and functions as a diffusion prevention layer between the silicon substrate 101 and the extraction interconnects 110a and 110b.

The tip of the extraction interconnect 110a enters the notch 108c formed in the peripheral portion 107b of the conductor film 107, and is connected to the peripheral portion 105b of the n-type region 105 (lower electrode) through the connection via 106c. The peripheral portion 105b is connected to the central portion 107a of the conductor film 107 (upper electrode) through the connection via 106b and the extension 109b.

On the other hand, the extraction interconnect 110b is connected to the peripheral portion 107b of the conductor film 107 (upper electrode). The peripheral portion 107b is connected to the central portion 105a of the n-type region 105 (lower electrode) through the extension 109a and the connection via 106a.

Thus, one extraction interconnect 110a is connected to the peripheral portion 105b of the n-type region 105 (lower electrode) and the central portion 107a of the conductor film 107 (upper electrode), and the other extraction interconnect 110b is connected to the peripheral portion 107b of the conductor film 107 (upper electrode) and the central portion 105a of the n-type region 105 (lower electrode). Hence, the equivalent circuit shown in FIG. 6 is implemented.

In this example, a large electrical signal can be extracted even if opposite polarizations occur in the central portion and the peripheral portion of the membrane, because the portions charged with the same polarity are connected to each other. Furthermore, as compared with the above first and second example, the entire region of the membrane can be used as a detector, achieving high area efficiency and high charge sensitivity.

Next, an electrode layout for achieving high voltage sensitivity is described.

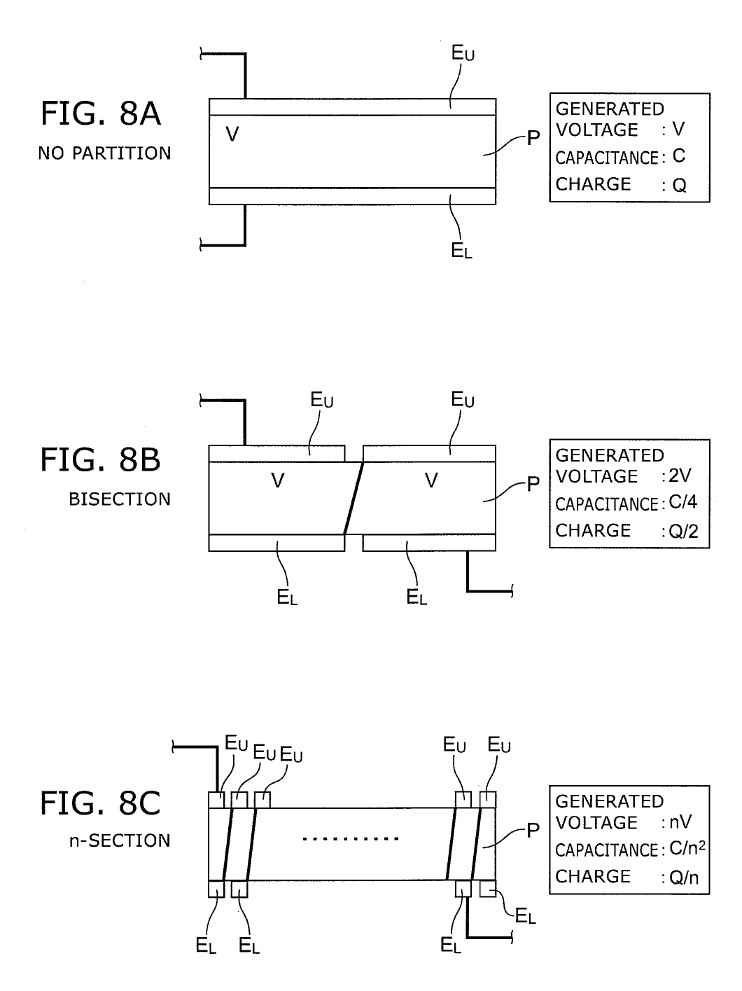

FIGS. 8A to 8C illustrate how the partition number of the capacitance is related to the generated voltage, capacitance, and charge, where FIG. 8A shows the case without partitioning the capacitance, FIG. 8B shows the case of bisecting the capacitance, and FIG. 8C shows the case of n-secting the capacitance (n is a natural number).

As shown in FIG. 8A, suppose that a lower electrode EL, a piezoelectric film P, and an upper electrode EU are formed entirely in the membrane to form a single capacitance, and denote the voltage generated across this capacitance by V, the capacitance by C, and the charge by Q. Here, in contrast to the above first to third example, assume that polarization with the same polarity occurs uniformly throughout the membrane.

As shown in FIG. 8B, in the same membrane, if the capacitance is partitioned into two equal parts in terms of area and they are connected in series, then the generated voltage is 2V, the capacitance is C/4, and the charge is Q/2. Furthermore, as shown in FIG. 8C, in the same membrane, if the capacitance is partitioned into n equal parts in terms of area and they are connected in series, then the generated voltage is nV, the capacitance is C/n², and the charge is Q/n. Thus, if the capacitance is partitioned into parts in the membrane and they are connected in series, then a large signal voltage can be extracted, and the voltage sensitivity is significantly enhanced, although the capacitance decreases.

In the following, a fourth example is described, where the capacitance is thus partitioned to enhance voltage sensitivity.

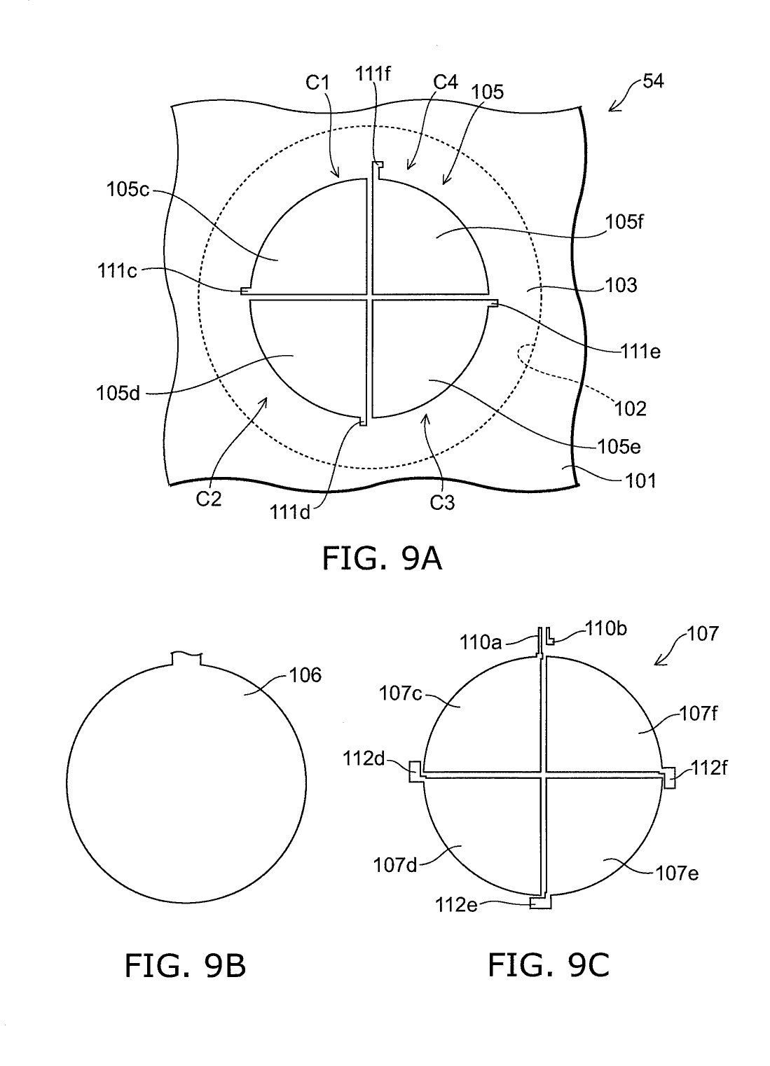

FIGS. 9A to 9C are plan views illustrating a piezoelectric device according to the fourth example, where FIG. 9A shows an SOI substrate provided with a lower electrode, FIG. 9B shows a piezoelectric film, and FIG. 9C shows an upper electrode.

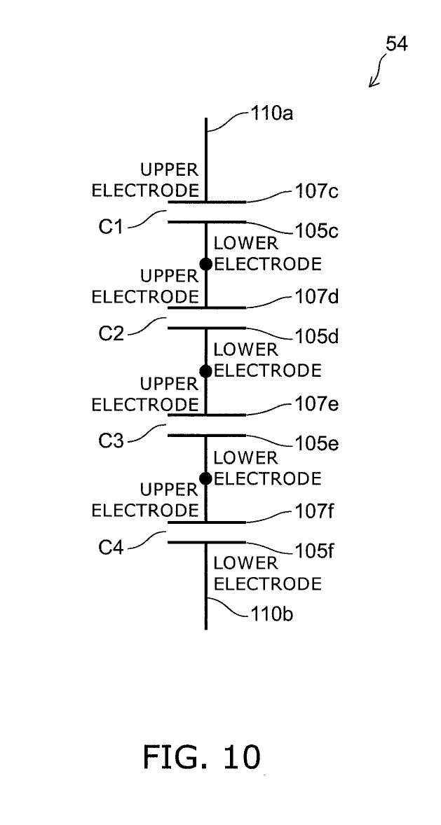

FIG. 10 is an equivalent circuit diagram of the piezoelectric device according to the fourth example.

As shown in FIG. 9A, in the piezoelectric device 54 according to this example, the silicon substrate 101, the cavity 102, and the silicon film 103 have the same configuration as in the above third example. In this example, an n-type region 105 (lower electrode) is formed only in the central portion of the silicon film 103. As a whole, the n-type region 105 is formed in a generally circular region, and partitioned into four generally equal parts 105c, 105d, 105e, and 105f. Each part is shaped like a sector having a central angle of 90 degrees. Extensions 111c, 111d, 111e, and 111f extending in the radial direction of the silicon film 103 are provided at the outer periphery of the parts 105c, 105d, 105e, and 105f, respectively.

As shown in FIG. 9B, a circular piezoelectric film 106 slightly larger than the n-type region 105 is provided on the n-type region 105 so as to cover the n-type region 105. The piezoelectric film 106 is a single continuous film and includes no connection vias. As viewed from above, the piezoelectric film 106 exists inside the cavity 102.

As shown in FIG. 9C, a conductor film 107 serving as an upper electrode is formed on the piezoelectric film 106. Like the n-type region 105 (lower electrode), the conductor film 107 is also partitioned into four sectoral parts 107c, 107d, 107e, and 107f. The parts 107c, 107d, 107e, and 107f are placed immediately above the parts 105c, 105d, 105e, and 105f, respectively. Extensions 112d, 112e, and 112f extending along the outer edge of the silicon film 103 are provided at the outer periphery of the parts 107d, 107e, and 107f, respectively.

Thus, the part 105c and the part 107c form a capacitance C1 (see FIG. 10) across a portion of the piezoelectric film 106, the part 105d and the part 107d form a capacitance C2 across another portion of the piezoelectric film 106, the part 105e and the part 107e form a capacitance C3 across still another portion of the piezoelectric film 106, and the part 105f and the part 107f form a capacitance C4 across still another portion of the piezoelectric film 106. That is, the membrane includes four capacitances.

The extension 112 of each capacitance reaches immediately above the extension 111 of the neighboring capacitance, and a contact (not shown) is provided between these extensions. Specifically, the extension 112f provided in the part 107f serving as the upper electrode of the capacitance C4 reaches immediately above the extension 111e provided in the part 105e serving as the lower electrode of the capacitance C3, the extension 112e provided in the part 107e serving as the upper electrode of the capacitance C3 reaches immediately above the extension 111d provided in the part 105d serving as the lower electrode of the capacitance C2, and the extension 112d provided in the part 107d serving as the upper electrode of the capacitance C2 reaches immediately above the extension 111c provided in the part 105c serving as the lower electrode of the capacitance C1, each being connected through a contact.

Furthermore, the piezoelectric device 54 includes a pair of extraction interconnects 110a and 110b. The extraction interconnect 110a is connected to the part 107c of the conductor film 107 serving as the upper electrode of the capacitance C1. The tip of the extraction interconnect 110b is located immediately above the extension 111f of the part 105f of the n-type region 105 and connected to the extension 111f through a contact. Thus, the extraction interconnect 110b is connected to the part 105f serving as the lower electrode of the capacitance C4.

Thus, as shown in FIG. 10, the extraction interconnect 110a is connected to the upper electrode (part 107c) of the capacitance C1, the lower electrode (part 105c) of this capacitance C1 is connected to the upper electrode (part 107d) of the capacitance C2 through the extension 111c, the contact (not shown), and the extension 112d, the lower electrode (part 105d) of this capacitance C2 is connected to the upper electrode (part 107e) of the capacitance C3 through the extension 111d, the contact (not shown), and the extension 112e, the lower electrode (part 105e) of this capacitance C3 is connected to the upper electrode (part 107f) of the capacitance C4 through the extension 111e, the contact (not shown), and the extension 112f, and the lower electrode (part 105f) of this capacitance C4 is connected to the extraction interconnect 110b through the extension 111f and the contact (not shown).

Thus, in the piezoelectric device 54, the four capacitances C1, C2, C3, and C4 are connected in series between the extraction interconnect 110a and the extraction interconnect 110b by electrically connecting the lower electrode of a certain capacitance to the upper electrode of another capacitance. In the current pathway from the extraction interconnect 110a to the interconnect 110b through the capacitances C1-C4, the upper electrodes of the respective capacitances are located on the extraction interconnect 110a side and the lower electrodes of the respective capacitances are located on the extraction interconnect 110b side. That is, the vertical directions of the respective capacitances with respect to the above current pathway are the same with respect to each other. Here, “the vertical direction of the capacitances” denotes the direction from the lower electrode of the respective capacitances to the upper electrode of the respective capacitances. In the following, such connections are referred to as “connections in the same direction.”

In this example, the capacitance is formed only in the central portion of the membrane. Hence, the voltage generated in the central portion is not canceled by the voltage with the opposite polarity generated in the peripheral portion, and a large electrical signal can be extracted. Furthermore, as described above, the capacitance is partitioned into four equal parts and they are connected in series in the same direction. Hence, the voltage can be four times higher than in the case of providing a single capacitance, and thus the voltage sensitivity can be enhanced. The configuration, operation, and effect of this example other than the foregoing are the same as those of the above third example.

The partition number of the n-type region 105 and the conductor film 107 is not limited to four, but can be an arbitrary number. In this case, this example can be expressed as follows. Let m be an integer of 2 or more. The n-type region 105 and the conductor film 107 each have m parts spaced from each other. The k-th (k is an integer of 1 to m) part of the conductor film 107 is placed immediately above the k-th part of the n-type region 105. The first part of the conductor film 107 is connected to the extraction interconnect 110a, the j-th (j is an integer of 1 to (m−1)) part of the n-type region 105 is connected to the (j+1)-th part of the conductor film 107, and the m-th part of the n-type region 105 is connected to the extraction interconnect 110b. As viewed from above, that is, in the direction perpendicular to the upper surface of the silicon film 103, the silicon film 103 and the piezoelectric film 106 have a circular shape, and the parts of the n-type region 105 and the conductor film 107 are respectively placed at m-fold symmetric positions with respect to the center of the silicon film 103.

Next, a fifth example is described.

This example is a combination of the method for enhancing charge sensitivity described in the above third example and the means for enhancing voltage sensitivity described in the above fourth example.

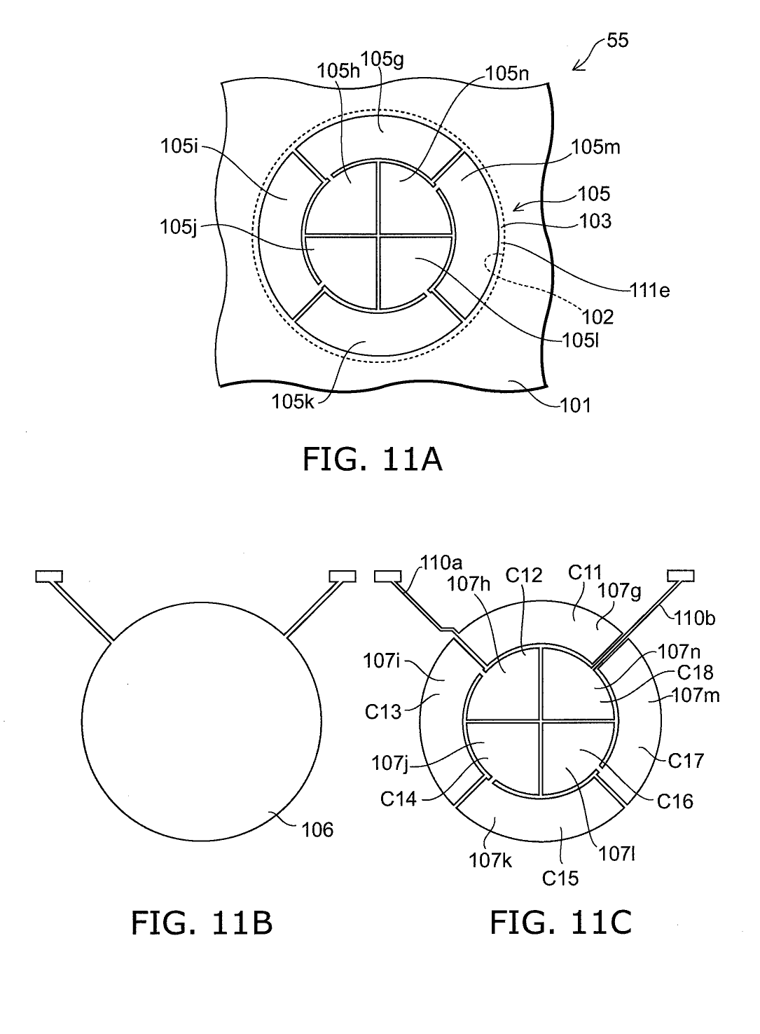

FIGS. 11A to 11C are plan views illustrating a piezoelectric device according to the fifth example, where FIG. 11A shows an SOI substrate provided with a lower electrode, FIG. 11B shows a piezoelectric film, and FIG. 11C shows an upper electrode.

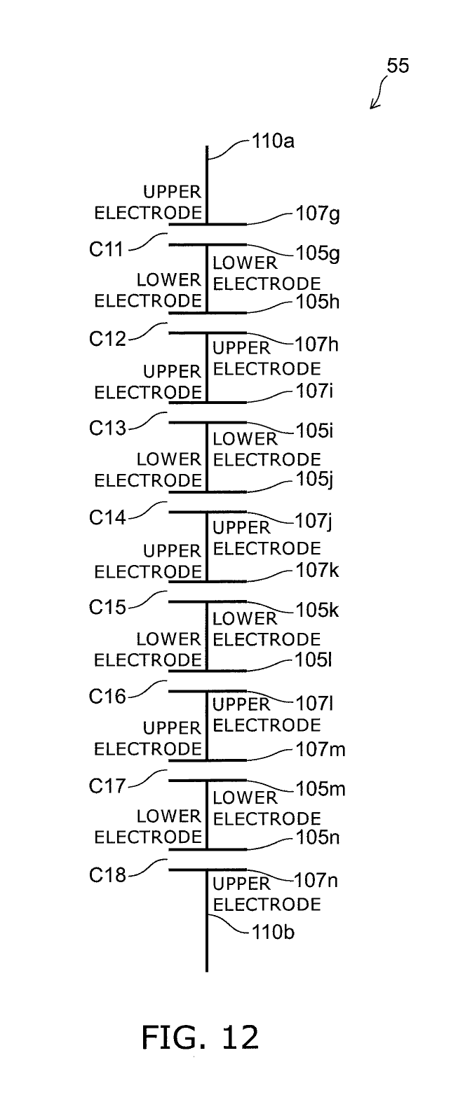

FIG. 12 is an equivalent circuit diagram of the piezoelectric device according to the fifth example.

As shown in FIG. 11A, in the piezoelectric device 55 according to this example, the silicon substrate 101, the cavity 102, and the silicon film 103 have the same configuration as in the above third example. In this example, an n-type region 105 (lower electrode) is formed in the entire region of the silicon film 103 and partitioned into eight parts. More specifically, in the central portion of the silicon film 103, four parts 105h, 105j, 105l, and 105n are placed. These parts are shaped like a sector having a central angle of 90 degrees. Furthermore, in the peripheral portion of the silicon film 103, four parts 105g, 105i, 105k, and 105m are placed. These parts have a shape as obtained by partitioning an annulus into four equal parts along the circumferential direction.

The four parts 105h, 105j, 105l, and 105n placed in the central portion of the silicon film 103 and the four parts 105g, 105i, 105k, and 105m placed in the peripheral portion thereof are respectively placed at fourfold symmetric positions with respect to the central axis of the silicon film 103, but shifted from each other by 45 degrees. Furthermore, the part 105g is linked to the part 105h, the part 105i is linked to the part 105j, the part 105k is linked to the part 105l, and the part 105m is linked to the part 105n.

As shown in FIG. 11B, a circular piezoelectric film 106 slightly larger than the n-type region 105 is provided on the n-type region 105 so as to cover the n-type region 105. The piezoelectric film 106 is a single continuous film and includes no connection vias.

As shown in FIG. 11C, a conductor film 107 serving as an upper electrode is formed on the piezoelectric film 106. Like the n-type region 105 (lower electrode), the conductor film 107 is also partitioned into eight parts 107g-107n. The parts 107g-107n are placed immediately above the parts 105g-105n, respectively. Furthermore, the part 107h is linked to the part 107i, the part 107j is linked to the part 107k, and the part 107l is linked to the part 107m. Thus, eight capacitances C11-C18 are formed on the silicon film 103. Furthermore, the extraction interconnect 110a is connected to the part 107g, and the extraction interconnect 110b is connected to the part 107n.

Thus, as shown in FIG. 12, the extraction interconnect 110a is connected to the upper electrode (part 107g) of the capacitance C11, the lower electrode (part 105g) of this capacitance C11 is connected to the lower electrode (part 105h) of the capacitance C12, the upper electrode (part 107h) of this capacitance C12 is connected to the upper electrode (part 107i) of the capacitance C13, the lower electrode (part 105i) of this capacitance C13 is connected to the lower electrode (part 105j) of the capacitance C14, the upper electrode (part 107j) of this capacitance C14 is connected to the upper electrode (part 107k) of the capacitance C15, the lower electrode (part 105k) of this capacitance C15 is connected to the lower electrode (part 105l) of the capacitance C16, the upper electrode (part 107l) of this capacitance C16 is connected to the upper electrode (part 107m) of the capacitance C17, the lower electrode (part 105m) of this capacitance C17 is connected to the lower electrode (part 105n) of the capacitance C18, and the upper electrode (part 107n) of this capacitance C18 is connected to the extraction interconnect 110b.

Thus, in the piezoelectric device 55, an upper electrode is connected to another upper electrode and a lower electrode is connected to another lower electrode between the capacitances formed in the peripheral portion and the capacitances formed in the central portion of the membrane. Thereby, the capacitances C11-C18 are connected in series between the extraction interconnect 110a and the extraction interconnect 110b, and the vertical directions of the respective capacitances with respect to the current pathway from the extraction interconnect 110a to the extraction interconnect 110b are opposite with respect to between the capacitances in the peripheral portion and the capacitances in the central portion. Namely, as to the capacitances C11, C13, C15, and C17 formed in the peripheral portion, the upper electrode is located on the extraction interconnect 110a side and the lower electrode is located on the extraction interconnect 110b side. Furthermore, as to the capacitances C12, C14, C16, and C18 formed in the central portion, the lower electrode is located on the extraction interconnect 110a side and the upper electrode is located on the extraction interconnect 110b side. Hereinafter, such connections are referred to as “connections in opposite directions.”

In this example, the capacitance is partitioned into the central portion and the peripheral portion of the membrane, and the capacitance of the central portion and the capacitance of the peripheral portion are connected in opposite directions with respect to each other. Hence, even if the central portion and the peripheral portion of the membrane generate polarization in opposite directions with respect to each other, the generated voltages are not canceled out, and a large electrical signal can be extracted. Furthermore, the capacitance is partitioned into four equal parts and they are connected in series in each of the central portion and the peripheral portion. Hence, the voltage sensitivity can be approximately eight times higher than in the above third example.

The partition number of the n-type region 105 and the conductor film 107 is not limited to eight, but can be an arbitrary number. In this case, this example can be generally expressed as follows. In each of the central portion and the peripheral portion of the silicon film 103, the n-type region 105 is partitioned into as many parts. The conductor film 107 is partitioned likewise, and each part of the conductor film 107 is placed immediately above the corresponding part of the n-type region 105. A piezoelectric film 106 is interposed between the n-type region 105 and the conductor film 107. Thus, each part of the n-type region 105, the corresponding part of the conductor film 107, and the piezoelectric film 106 therebetween constitute a capacitance. The capacitances placed in the central portion of the silicon film 103 and the capacitances placed in the peripheral portion thereof are connected in opposite directions with respect to each other and connected in series as a whole. Furthermore, both ends of the series circuit with all these capacitances connected in series are connected to a pair of extraction interconnects.

More specifically, suppose that m (m is an integer of 2 or more) is the partition number of the n-type region 105 in the central portion of the silicon film 103. Then, the partition number of the conductor film 107 in the central portion, the partition number of the n-type region 105 in the peripheral portion, and the partition number of the conductor film 107 in the peripheral portion are each also equal to m. The first part of the conductor film 107 in the peripheral portion is connected to the extraction interconnect 110a, the first part of the n-type region 105 in the peripheral portion serving as the lower electrode of this capacitance is connected to the first part of the n-type region 105 in the central portion, the first part of the conductor film 107 in the central portion serving as the upper electrode of this capacitance is connected to the second part of the conductor film 107 in the peripheral portion, and the second part of the n-type region 105 in the peripheral portion is connected to the second part of the n-type region 105 in the central portion. Continuing likewise, the j-th (j is an integer of 1 to (m−1)) part of the n-type region 105 in the peripheral portion is connected to the j-th part of the n-type region 105 in the central portion, and the j-th part of the conductor film 107 in the central portion is connected to the (j+1)-th part of the conductor film 107 in the peripheral portion. Furthermore, the m-th part of the conductor film 107 in the central portion is connected to the extraction interconnect 110b. Thus, the above series circuit is configured. As viewed from above, the silicon film 103 and the piezoelectric film 106 have a circular shape, and the parts of the n-type region 105 and the conductor film 107 are respectively placed at m-fold symmetric positions with respect to the center of the silicon film 103.

Next, a sixth example is described.

This example is a combination of the method for enhancing charge sensitivity described in the above third example and means for enhancing capacitance by parallel division.

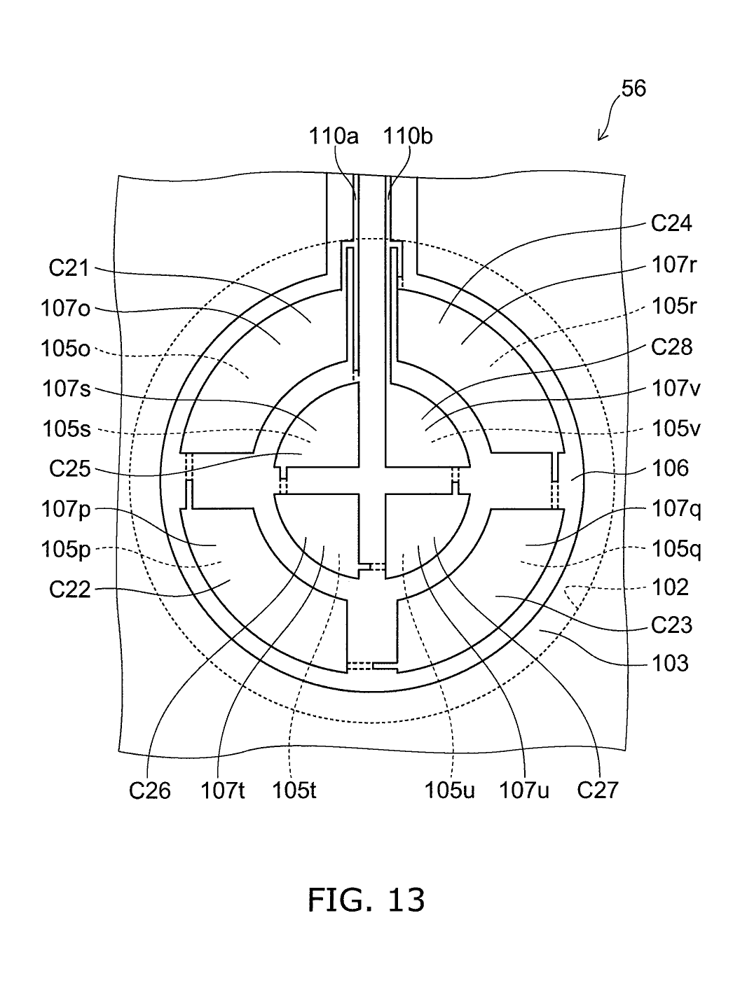

FIG. 13 is a plan view illustrating a piezoelectric device according to the sixth example.

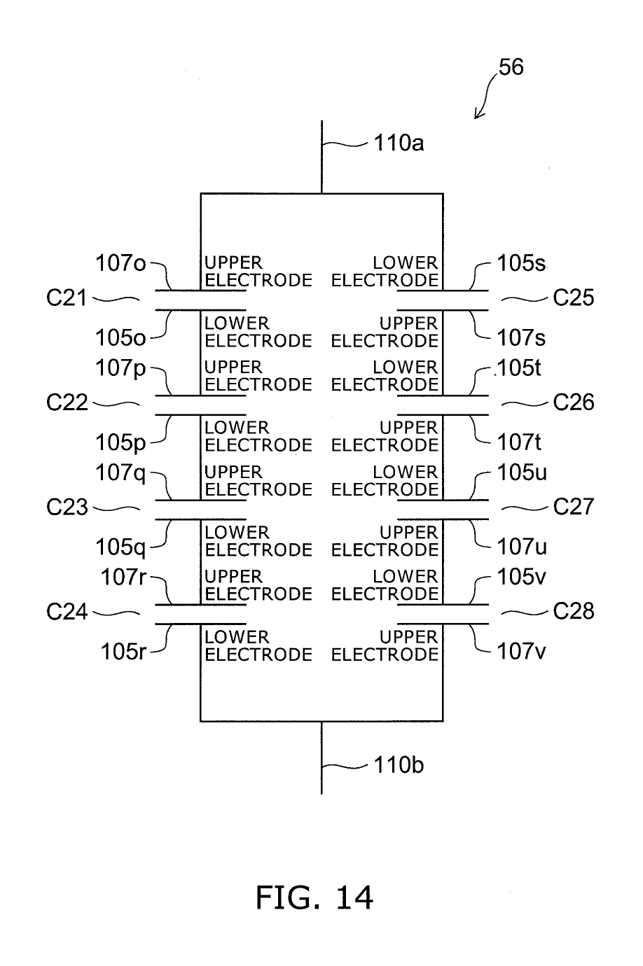

FIG. 14 is an equivalent circuit diagram of the piezoelectric device according to the sixth example.

As shown in FIG. 13, in the piezoelectric device 56 according to this example, the silicon substrate 101, the cavity 102, and the silicon film 103 have the same configuration as in the above third example. In this example, like the above fifth example, an n-type region 105 (lower electrode) is formed in the entire region of the silicon film 103 and partitioned into eight parts, and the conductor film 107 is also partitioned into eight parts. As viewed from above, the conductor film 107 and the n-type region 105 have the same shape, and each part of the conductor film 107 is placed immediately above the corresponding part of the n-type region 105.

More specifically, in the peripheral portion of the silicon film 103, four parts 105o, 105p, 105q, and 105r of the n-type region 105 are placed. These parts have a shape as obtained by partitioning an annulus into four equal parts along the circumferential direction. Furthermore, in the central portion of the silicon film 103, four parts 105s, 105t, 105u, and 105v are placed. These parts are shaped like a sector having a central angle of 90 degrees. The four parts 105o, 105p, 105q, and 105r placed in the peripheral portion of the silicon film 103 and the four parts 105s, 105t, 105u, and 105v placed in the central portion thereof are respectively placed at fourfold symmetric positions with respect to the central axis of the silicon film 103, and located in the same direction as viewed from the central axis. Furthermore, eight parts 107o-107v of the conductor film 107 are placed immediately above the eight parts 105o-105v of the n-type region 105, respectively.

Furthermore, a piezoelectric film 106 is provided between the n-type region 105 and the conductor film 107. The piezoelectric film 106 has a circular shape. Its size is slightly larger than the region occupied by the n-type region 105 and the conductor film 107, and its outer edge is located slightly outside the region occupied by the n-type region 105 and the conductor film 107. However, the piezoelectric film 106 is smaller then the silicon film 103 and covers part of the upper surface of the silicon film 103. The piezoelectric film 106 is a single continuous film and includes a plurality of connection vias.

The part 105o and the part 107o form a capacitance C21, the part 105p and the part 107p form a capacitance C22, the part 105q and the part 107q form a capacitance C23, the part 105r and the part 107r form a capacitance C24, the part 105s and the part 107s form a capacitance C25, the part 105t and the part 107t form a capacitance C26, the part 105u and the part 107u form a capacitance C27, and the part 105v and the part 107v form a capacitance C28.

Furthermore, as shown in FIGS. 13 and 14, the extraction interconnects 110a and 110b are each split into two branches. One branch of the extraction interconnect 110a is connected to the upper electrode (part 107o) of the capacitance C21, the lower electrode (part 105o) of this capacitance C21 is connected to the upper electrode (part 107p) of the capacitance C22, the lower electrode (part 105p) of this capacitance C22 is connected to the upper electrode (part 107q) of the capacitance C23, the lower electrode (part 105q) of this capacitance C23 is connected to the upper electrode (part 107r) of the capacitance C24, the lower electrode (part 105r) of this capacitance C24 is connected to one branch of the extraction interconnects 110b.

On the other hand, the other branch of the extraction interconnect 110a is connected to the lower electrode (part 105s) of the capacitance C25, the upper electrode (part 107s) of this capacitance C25 is connected to the lower electrode (part 105t) of the capacitance C26, the upper electrode (part 107t) of this capacitance C26 is connected to the lower electrode (part 105u) of the capacitance C27, the upper electrode (part 107u) of this capacitance C27 is connected to the lower electrode (part 105v) of the capacitance C28, the upper electrode (part 107v) of this capacitance C28 is connected to the other branch of the extraction interconnects 110b. Thus, in the piezoelectric device 56, the capacitances C21-C24 are connected in series in the same direction between the extraction interconnect 101a and the extraction interconnect 110b. Furthermore, the capacitances C25-C28 are connected in series in the same direction between the extraction interconnect 110a and the extraction interconnect 110b. On this occasion, the vertical direction of the capacitances C21-C24 and the vertical direction of the capacitances C25-C28 are mutually opposite with respect to the current pathway from the extraction interconnect 110a to the extraction interconnect 110b. Namely, the series circuit composed of the capacitances C21-C24 and the series circuit composed of the capacitances C25-C28 are connected in parallel to each other in the opposite directions.

In this example, the capacitance is partitioned into the central portion and the peripheral portion of the membrane, and the capacitance of the central portion and the capacitance of the peripheral portion are connected in opposite directions with respect to each other. Hence, even if the central portion and the peripheral portion of the membrane generate polarization in opposite directions with respect to each other, the generated voltages are not canceled out, and a large electrical signal can be extracted. Furthermore, the capacitance is partitioned into four equal parts and they are connected in series in each of the central portion and the peripheral portion. Hence, the voltage sensitivity can be four times higher than in the above third example. Furthermore, the series circuit formed in the central portion and the series circuit formed in the peripheral portion are connected in parallel to each other. Hence, as compared with the above fifth example, the capacitance can be increased. Thus, the characteristics of the piezoelectric device 56 can be enhanced as a whole.

The partition number of the n-type region 105 and the conductor film 107 is not limited to eight, but can be an arbitrary number. In this case, this example can be generally expressed as follows. In each of the central portion and the peripheral portion of the silicon film 103, the n-type region 105 is partitioned into a plurality of parts. The conductor film 107 is partitioned likewise, and each part of the conductor film 107 is placed immediately above the corresponding part of the n-type region 105. A piezoelectric film 106 is interposed between the n-type region 105 and the conductor film 107. Thus, each part of the n-type region 105, the corresponding part of the conductor film 107, and the piezoelectric film 106 therebetween constitute a capacitance. The capacitances placed in the central portion of the silicon film 103 are connected in series in the same direction with respect to each other to constitute a first series circuit, and the capacitances placed in the peripheral portion are also connected in series in the same direction with respect to each other to constitute a second series circuit. Furthermore, the first series circuit and the second series circuit are connected in parallel between a pair of extraction interconnects. Here, the direction of the capacitances in the first series circuit is opposite to that in the second series circuit. In this example, the partition number of the n-type region 105 and the conductor film 107 in the central portion of the silicon film 103 is illustratively the same as the partition number of the n-type region 105 and the conductor film 107 in the peripheral portion of the silicon film 103. However, this embodiment is not limited thereto, but they may be different from each other.

More specifically, suppose that m (m is an integer of 2 or more) is the partition number of the n-type region 105 in the central portion of the silicon film 103. Then, the partition number of the conductor film 107 in the central portion is also equal to m. The first part of the n-type region 105 in the central portion is connected to the extraction interconnect 110a, the first part of the conductor film 107 in the central portion serving as the upper electrode of this capacitance is connected to the second part of the n-type region 105 in the central portion. That is, the j-th (j is an integer of 1 to (m−1)) part of the conductor film 107 in the central portion is connected to the (j+1)-th part of the n-type region 105 in the central portion. Furthermore, the m-th part of the conductor film 107 in the central portion is connected to the extraction interconnect 110b. Thus, the above first series circuit is connected between the extraction interconnect 110a and the extraction interconnect 110b.

On the other hand, suppose that n (n is an integer of 2 or more) is the partition number of the n-type region 105 in the peripheral portion. Then, the partition number of the conductor film 107 in the peripheral portion is also equal to n. The first part of the conductor film 107 in the peripheral portion is connected to the extraction interconnect 110a, the first part of the n-type region 105 in the peripheral portion serving as the lower electrode of this capacitance is connected to the second part of the conductor film 107 in the peripheral portion, and the second part of the n-type region 105 in the peripheral portion serving as the lower electrode of this capacitance is connected to the third part of the conductor film 107 in the peripheral portion. That is, the i-th (i is an integer of 1 to (n−1)) part of the n-type region 105 in the peripheral portion is connected to the (i+1)-th part of the conductor film 107 in the peripheral portion. Furthermore, the n-th part of the n-type region 105 in the peripheral portion is connected to the extraction interconnect 110b. Thus, the above second series circuit is connected between the extraction interconnect 110a and the extraction interconnect 110b.

Furthermore, the order of connection of the n-type region 105 (lower electrode) and the conductor film 107 (upper electrode) in the first series circuit is opposite to that in the second series circuit. This results in the above parallel circuit. As viewed from above, the silicon film 103 and the piezoelectric film 106 have a circular shape, and the parts of the n-type region 105 and the conductor film 107 in the central portion are respectively placed at m-fold symmetric positions with respect to the center of the silicon film 103. Furthermore, the parts of the n-type region 105 and the conductor film 107 in the peripheral portion are respectively placed at n-fold symmetric positions with respect to the center of the silicon film 103. It is noted that in this example, m and n are each equal to four.

To realize the electrode layout described in the first to sixth example without losing the structural strength of the membrane, it is useful to form the lower electrode from the diffusion region as in this embodiment. Furthermore, even in the case where the electrode layout as in these examples is not used, the method of partitioning the electrode may be effective in reducing the parasitic capacitance in the support portion.

Hereinafter, variations of the membrane shape in this embodiment are described.

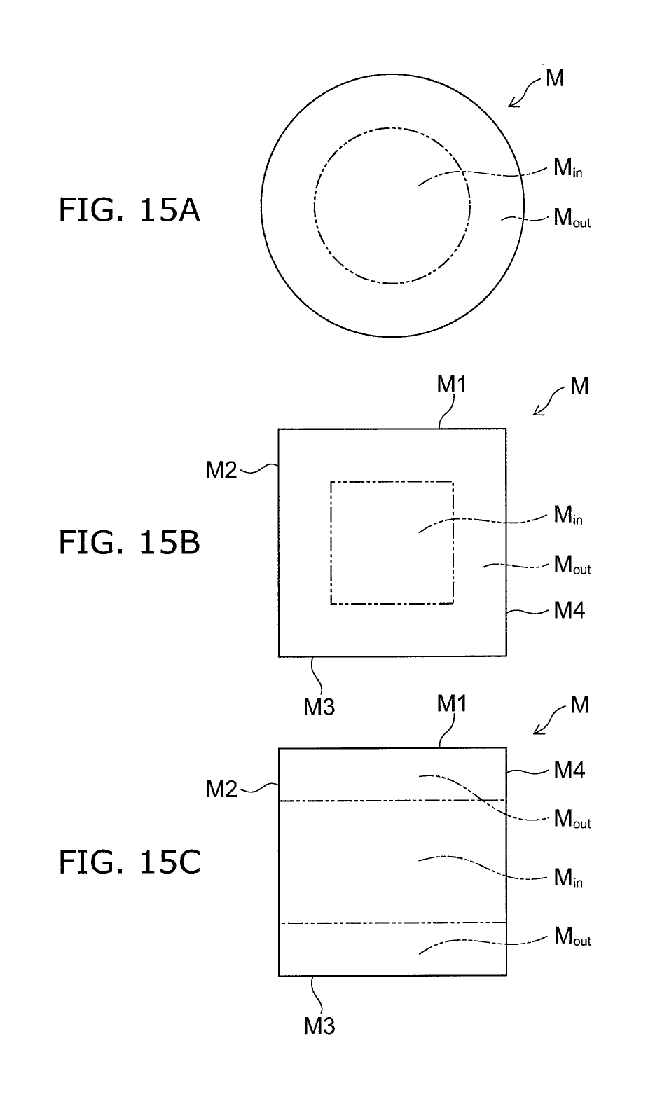

FIGS. 15A to 15C are schematic plan views illustrating the variations of the membrane shape in this embodiment. More specifically, FIG. 15A shows the case where the membrane has a circular shape, FIG. 15B shows the case where the membrane has a quadrangular shape and all the ends are fixed, and FIG. 15C shows the case where the membrane has a quadrangular shape and a pair of the ends opposed to each other are fixed and another pair of the ends are free.

FIGS. 15A to 15C show only the membrane and the description of the circumference thereof is omitted.

As shown in FIG. 15A, in the above examples, the shape of the membrane M is circular as viewed from above. In this case, the central portion Mᵢₙ of the membrane M has a circular shape and the peripheral portion Mₒᵤₜ thereof has an annular shape. As described above, the directions of electric field generated when the membrane M bends are opposite to each other between in the central portion Mᵢₙ and in the peripheral portion Mₒᵤₜ. As illustrated in this embodiment, when forming the cavity by deep RIE, a circular shape for the cavity facilitates processes.

However, the shape of the membrane in this embodiment is not limited to circular. For example, in the case where the cavity is formed by a wet etching, since the crystal orientation of the silicon substrate is anisotropic, the shape of the cavity is quadrangular as viewed from above. Therefore, the membrane M also has a quadrangular shape.

As shown in FIG. 15B, when the membrane M has a quadrangular shape and all the ends M1-M4 are fixed, the central portion Mᵢₙ of the membrane M has a quadrangular shape and the peripheral portion Mₒᵤₜ thereof has a frame-like shape. In this case, the electrodes of the respective capacitances are located inside the central portion Mᵢₙ having a quadrangular shape and inside the peripheral portion Mₒᵤₜ having a frame-like shape.

As shown in FIG. 15C, in the case where the membrane M has a quadrangular shape and is shaped like a fixed-fixed beam, that is, out of the four ends of the membrane M, a pair of the ends M1 and M3 opposed to each other are fixed and another pair of the ends M2 and M4 are free, the peripheral portions Mₒᵤₜ of the membrane M have the shape of a pair of strips disposed along the fixed ends M1 and M3, and the central portion Mᵢₙ of the membrane M has a quadrangular shape sandwiched by a pair of the peripheral portions Mₒᵤₜ. In this case, the electrodes of the respective capacitances are located inside the central portion Mᵢₙ having a quadrangular shape and inside the peripheral portions Mₒᵤₜ having a strip shape.

The shape of the membrane is not limited to these examples and may be, for example, elliptic or the like.

Next, a second embodiment of the invention is described.

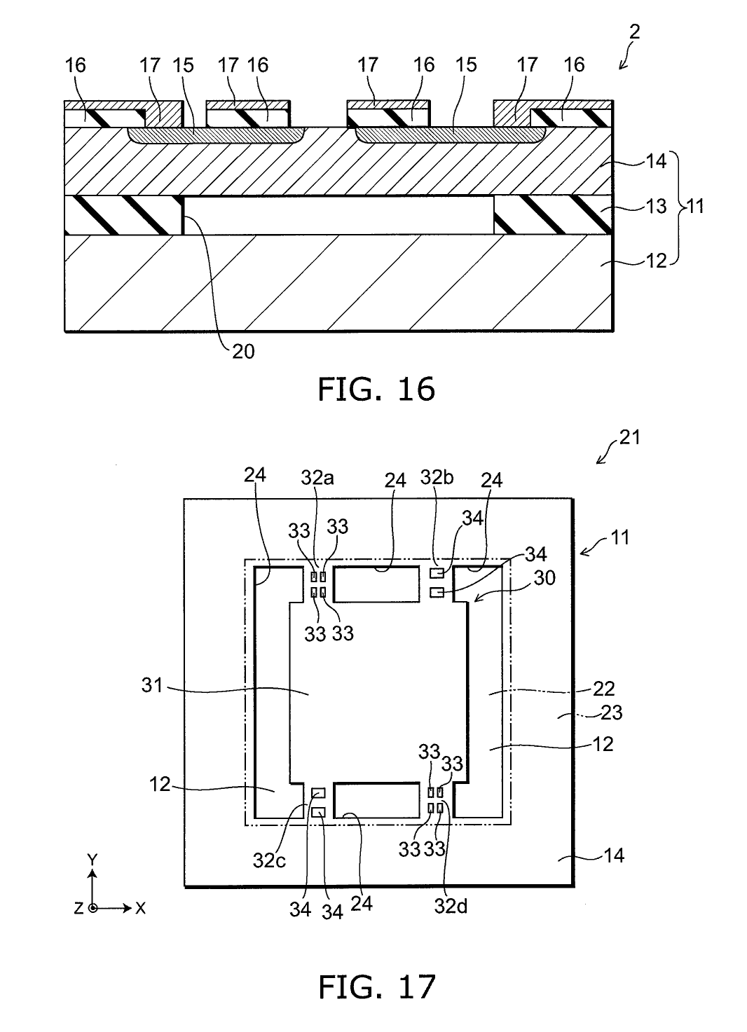

FIG. 16 is a cross-sectional views illustrating a piezoelectric device according to this embodiment.

The piezoelectric device 2 according to this embodiment is a MEMS device fabricated using an SOI substrate, specifically an angular velocity sensor.

As shown in FIG. 16, the piezoelectric device 2 is different from the piezoelectric device 1 (see FIG. 1) according to the above first embodiment in that the support matrix 12 of the SOI substrate 11 is not removed, but only the BOX layer 13 is removed. Thus, a cavity 20 is formed in the portion between the support matrix 12 and the silicon layer 14 where the BOX layer 13 is removed, and the inside of the cavity 20 is an air layer. The support matrix 12 and the silicon layer 14 are opposed to each other across the cavity 20.

Furthermore, the piezoelectric device 2 is different from the piezoelectric device 1 (see FIG. 1) according to the first embodiment in the layout of the n-type region 15 serving as a lower electrode, the piezoelectric film 16, and the conductor film 17 serving as an upper electrode. Moreover, the layout of the through hole (not shown) formed in the silicon layer 14 is also different from that of the first embodiment. The configuration of this embodiment other than the foregoing is the same as that of the above first embodiment.

Next, a method for manufacturing the piezoelectric device 2 according to this embodiment is described.

An n-type region 15 is formed in the silicon layer 14 of the SOI substrate 11, and a piezoelectric film 16 and a conductor film 17 are formed on the SOI substrate 11. Then, RIE using a chlorine-based gas or fluorine-based gas is performed on the silicon layer 14 to form a through hole (not shown) reaching the BOX layer 13. The manufacturing method so far is the same as that of the above first embodiment.

Next, from the upper surface side of the SOI substrate 11, through this through hole, BHF or hydrogen fluoride (HF) gas is used to etch the BOX layer 13 to remove part of the BOX layer 13. Thus, in the central region of the piezoelectric device 2, a cavity 20 is formed between the support matrix 12 and the silicon layer 14. Thus, the piezoelectric device 2 is manufactured.

Next, the operation of the piezoelectric device 2 according to this embodiment is described.

Like the above first embodiment, also in the piezoelectric device 2, the n-type region 15 functions as a lower electrode, and the conductor film 17 functions as an upper electrode. Thus, a piezoelectric element is configured, where the piezoelectric film 16 is sandwiched between the n-type region 15 and the conductor film 17.

Like the first embodiment, part of this piezoelectric element functions as a sensing element for sensing the deformation of the silicon layer 14 and converting it into an electrical signal. However, in contrast to the above first embodiment, the rest of the piezoelectric element functions as a driving element for vibrating the silicon layer 14 in response to an electrical signal. Consequently, in the piezoelectric device 2, while the driving element is vibrating the silicon layer 14, the Coriolis force generated in the silicon layer 14 is detected by the sensing element to sense the angular velocity of the piezoelectric device 2. Thus, the piezoelectric device 2 functions as an angular velocity sensor.

Next, the effect of this embodiment is described.

According to this embodiment, the piezoelectric film 16 and the conductor film 17 as the upper electrode constituting the driving element, and the piezoelectric film 16 and the conductor film 17 constituting the sensing element can be all formed on the flat silicon layer 14. Hence, the piezoelectric film is highly oriented, achieving good piezoelectric characteristics. Furthermore, the membrane is free from breakage, achieving high mechanical reliability. The effect of this embodiment other than the foregoing is the same as that of the above first embodiment.

Next, an example of the above second embodiment is described.

FIG. 17 is a plan view illustrating an angular velocity sensor according to this example.

The angular velocity sensor according to this example is a piezoelectric device, which is a MEMS device fabricated using an SOI substrate.

As shown in FIG. 17, the angular velocity sensor 21 according to this example is formed on the SOI substrate 11. The central region of the SOI substrate 11 is a sensor region 22, and the peripheral region is a circuit region 23. In the circuit region 23, transistors and the like are formed in the silicon layer 14 to form a driving circuit for the angular velocity sensor 21.

In the sensor region 22, the BOX layer 13 (see FIG. 16) is removed to form a cavity 20. Furthermore, the silicon layer 14 is partly removed to form a through hole 24. The portion of the silicon layer 14 partitioned by the cavity 20 and the through hole 24 from the other portion constitutes a base film of the membrane 30.

The base film of the membrane 30 includes a rectangular body portion 31 and a plurality of, e.g. four, bridge portions 32a-32d (hereinafter also collectively referred to as “bridge portions 32”) linked near the corner of the body portion 31. The body portion 31 is not in contact with the members other than the bridge portions 32, and is vibratile supported through the four bridge portions 32. In the following, for convenience of description, the extending direction of the bridge portions 32 is taken as the Y direction, the direction parallel to the surface of the base film and orthogonal to the Y direction is taken as the X direction, and the direction orthogonal to both the Y and X directions is taken as the Z direction.

Four driving elements 33 are provided on each of the bridge portions 32a and 32d located diagonally with respect to each other. These four driving elements 33 are arranged in a 2×2 matrix. Furthermore, two sensing elements 34 are provided on each of the bridge portions 32b and 32c, and arranged along the Y direction. As described in the above second embodiment, the driving element 33 and the sensing element 34 are each composed of the n-type region 15 serving as the lower electrode, the piezoelectric film 16, and the conductor film 17 serving as the upper electrode. The base film, the driving elements 33, and the sensing elements 34 constitute the membrane 30.

Next, the operation of this example is described.

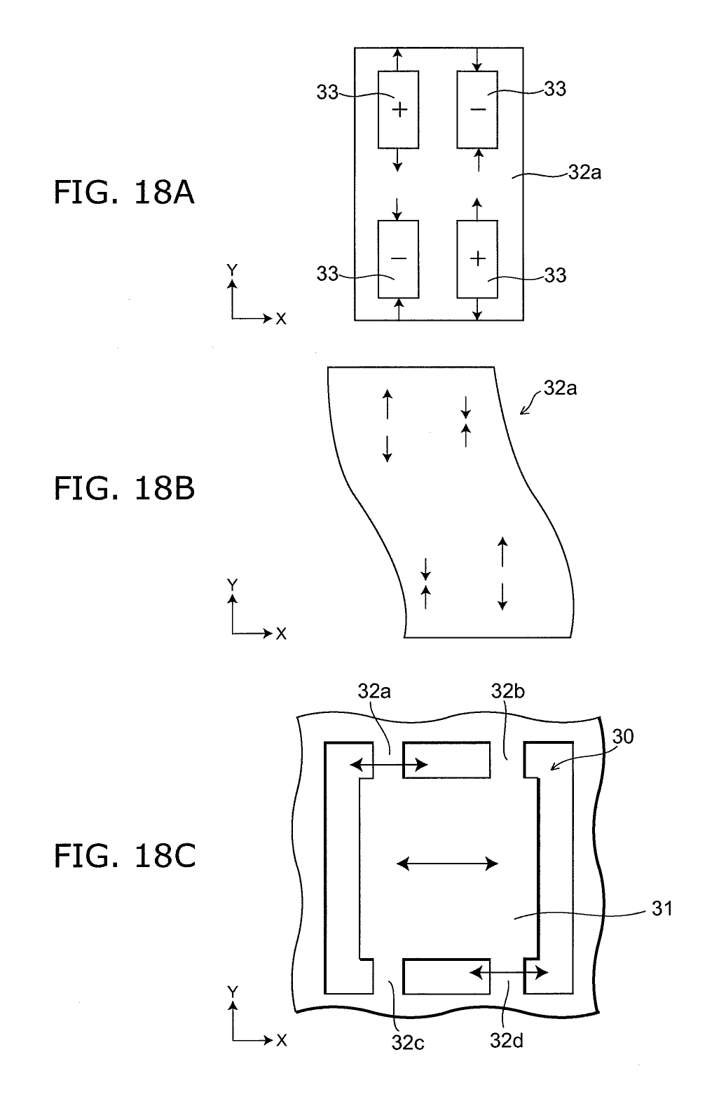

FIGS. 18A to 18C are plan views illustrating the operation of the angular velocity sensor according to this example.

As shown in FIG. 18A, the four driving elements 33 provided in the bridge portion 32a are grouped into two sets, each set consisting of two driving elements 33 located diagonally with respect to each other. For each set of driving elements 33, a voltage is applied between the upper electrode and the lower electrode. Here, the voltages applied to the different sets have opposite polarities.

Thus, as shown in FIG. 18B, the driving elements 33 in each set contract or expand, deforming the bridge portion 32a in the X direction. Similar voltages are applied also to the bridge portion 32d to deform it likewise. Consequently, as shown in FIG. 18C, the body portion 31 of the membrane 30 is displaced in the X direction. Thus, the body portion 31 is vibrated by periodically switching the polarity of the voltage applied to the driving elements 33. To enhance the detection sensitivity, the frequency of the AC voltage applied to the driving elements 33 needs to be set to a value close to the X-direction resonant frequency of the membrane 30.

When a rotation about the Y direction is applied to the angular velocity sensor 21 in this state, a Coriolis force is generated in the body portion 31 vibrating in the X direction, and the body portion 31 starts to vibrate in the Z direction. This vertically deforms the bridge portions 32. At this time, the sensing elements 34 provided in the bridge portions 32b and 32c detect this deformation, thereby sensing the angular velocity. The operation and effect of this example other than the foregoing are the same as those of the above second embodiment.

This example only illustrates a layout of the components in the second embodiment in a schematic manner, and does not necessarily correspond to actual products. In designing an actual product, detailed investigations are required in consideration of various factors. For example, in an angular velocity sensor, it is necessary to narrow the spacing (detuning) between the resonant frequency of the excited vibration and the resonant frequency of the vibration generated by the Coriolis force, and a detailed design is required for the shape, number, and layout of the detector (sensing elements 34) and the driver (driving elements 33). Hence, for the device structure implementing the second embodiment, numerous variations are possible other than this example.

The invention has been described with reference to the embodiments and examples. However, the invention is not limited to these embodiments and examples. For instance, those skilled in the art can suitably modify the above embodiments and examples by addition, deletion, or design change of components, or by addition, omission, or condition change of processes, and such modifications are also encompassed within the scope of the invention as long as they fall within the spirit of the invention. Although the piezoelectric device is illustratively a microphone and an angular velocity sensor in the above embodiments and examples, the invention is not limited thereto.

1. A piezoelectric device comprising:
a silicon substrate with a first-conductivity-type region formed in at least part of an upper portion thereof;
a second-conductivity-type region formed in the first-conductivity-type region and exposed to an upper surface of the silicon substrate;
a piezoelectric film provided on the silicon substrate, being in contact with the second-conductivity-type region, and made of a piezoelectric material; and
a conductor film provided on the piezoelectric film and made of a conductive material.

2. The device according to claim 1, wherein the first-conductivity-type region has a lower impurity concentration than the second-conductivity-type region.

3. The device according to claim 1, wherein the silicon substrate includes:
a base film with the second-conductivity-type region and at least part of the first-conductivity-type region formed therein; and
a support portion vibratile supporting the base film.

4. The device according to claim 3, wherein
the base film is made of a silicon layer, and
the support portion includes:
an insulating layer bonded to the silicon layer; and
a support matrix provided below the insulating layer.

5. The device according to claim 4, wherein the silicon layer is formed from single crystal silicon.

6. The device according to claim 1, wherein
the second-conductivity-type region includes:
a first region portion; and
a second region portion spaced from the first region portion, and
the conductor film includes:
a first film portion placed immediately above the first region portion and connected to the second region portion; and
a second film portion placed immediately above the second region portion and connected to the first region portion.

7. The device according to claim 6, wherein, as viewed in a direction perpendicular to the upper surface of the silicon substrate,
the first region portion and the first film portion have a circular shape, and
the second region portion and the second film portion have an annular shape surrounding the first region portion and the first film portion, respectively.

8. The device according to claim 7, wherein
the silicon substrate includes:
a base film with the second-conductivity-type region and at least part of the first-conductivity-type region formed therein; and
a support portion vibratile supporting the base film, and
the base film has a circular shape larger than the second-conductivity-type region.

9. The device according to claim 1, further comprising:
a first and second extraction interconnect,
the second-conductivity-type region and the conductor film being each partitioned into m parts, where m is an integer of 2 or more,
the k-th part of the conductor film being placed immediately above the k-th part of the second-conductivity-type region, where k is an integer of 1 to m,
the first part of the conductor film being connected to the first extraction interconnect,
the j-th part of the second-conductivity-type region being connected to the (j+1)-th part of the conductor film, where j is an integer of 1 to (m−1), and
the m-th part of the second-conductivity-type region being connected to the second extraction interconnect.

10. The device according to claim 9, wherein
the silicon substrate includes:
a base film with the second-conductivity-type region and at least part of the first-conductivity-type region formed therein; and
a support portion vibratile supporting the base film,
the base film and the piezoelectric film have a circular shape larger than the second-conductivity-type region, and
the parts of the second-conductivity-type region and the parts of the conductor film are respectively placed at m-fold symmetric positions with respect to the center of the base film.

11. The device according to claim 10, wherein the m is four.

12. The device according to claim 1, further comprising:
a first and second extraction interconnect,
the silicon substrate including:
a base film with the second-conductivity-type region and at least part of the first-conductivity-type region formed therein; and
a support portion vibratile supporting the base film,
in each of a central portion and a peripheral portion of the base film, the second-conductivity-type region and the conductor film being partitioned into as many parts, each part of the conductor film being placed immediately above a corresponding one of the parts of the second-conductivity-type region, and
a plurality of capacitances composed of the parts of the second-conductivity-type region, the parts of the conductor film, and the piezoelectric film therebetween being connected in series between the first extraction interconnect and the second extraction interconnect, the directions from the second-conductivity-type region to the conductor film in the respective capacitances with respect to a current pathway from the first extraction interconnect to the second extraction interconnect being opposite with respect to between the capacitances placed in the peripheral portion and the capacitances placed in the central portion.

13. The device according to claim 12, wherein
denoting by m each of the partition number of the second-conductivity-type region in the central portion, the partition number of the conductor film in the central portion, the partition number of the second-conductivity-type region in the peripheral portion, and the partition number of the conductor film in the peripheral portion, where m is an integer of 2 or more,
the k-th part of the conductor film is placed immediately above the k-th part of the second-conductivity-type region in each of the central portion and the peripheral portion, where k is an integer of 1 to m,
the first part of the conductor film in the peripheral portion is connected to the first extraction interconnect,
the j-th part of the second-conductivity-type region in the peripheral portion is connected to the j-th part of the second-conductivity-type region in the central portion, where j is an integer of 1 to (m−1),
the j-th part of the conductor film in the central portion is connected to the (j+1)-th part of the conductor film in the peripheral portion, and
the m-th part of the conductor film in the central portion is connected to the second extraction interconnect.

14. The device according to claim 13, wherein
the base film and the piezoelectric film have a circular shape larger than the second-conductivity-type region, and
the parts of the second-conductivity-type region and the parts of the conductor film are respectively placed at m-fold symmetric positions with respect to the center of the base film.

15. The device according to claim 1, further comprising:
a first and second extraction interconnect,
the silicon substrate including:
a base film with the second-conductivity-type region and at least part of the first-conductivity-type region formed therein; and
a support portion vibratile supporting the base film,
in each of a central portion and a peripheral portion of the base film, the second-conductivity-type region and the conductor film being partitioned into a plurality of parts, each part of the conductor film being placed immediately above a corresponding one of the parts of the second-conductivity-type region, and
a plurality of capacitances composed of the parts of the second-conductivity-type region, the parts of the conductor film, and the piezoelectric film therebetween placed in the central portion being connected in series between the first extraction interconnect and the second extraction interconnect so that the directions from the second-conductivity-type region to the conductor film in the respective capacitances with respect to a current pathway from the first extraction interconnect to the second extraction interconnect are the same with respect to each other,
a plurality of capacitances composed of the parts of the second-conductivity-type region, the parts of the conductor film, and the piezoelectric film therebetween placed in the peripheral portion being connected in series between the first extraction interconnect and the second extraction interconnect so that the directions from the second-conductivity-type region to the conductor film in the respective capacitances with respect to a current pathway from the first extraction interconnect to the second extraction interconnect are the same with respect to each other, and
a series circuit composed of a plurality of the capacitances placed in the central portion and a series circuit composed of a plurality of the capacitances placed in the peripheral portion being connected in parallel to each other between the first extraction interconnect and the second extraction interconnect so that the directions from the second-conductivity-type region to the conductor film in the respective capacitances with respect to a current pathway from the first extraction interconnect to the second extraction interconnect are opposite with respect to each other.

16. The device according to claim 15, wherein
denoting by m each of the partition number of the second-conductivity-type region in the central portion and the partition number of the conductor film in the central portion, where m is an integer of 2 or more, and denoting by n each of the partition number of the second-conductivity-type region in the peripheral portion and the partition number of the conductor film in the peripheral portion, where n is an integer of 2 or more,
in the central portion, the k-th part of the conductor film is placed immediately above the k-th part of the second-conductivity-type region, where k is an integer of 1 to m,
in the peripheral portion, the h-th part of the conductor film is placed immediately above the h-th part of the second-conductivity-type region, where h is an integer of 1 to n,
the first part of the second-conductivity-type region in the central portion is connected to the first extraction interconnect,
the j-th part of the conductor film in the central portion is connected to the (j+1)-th part of the second-conductivity-type region in the central portion, where j is an integer of 1 to (m−1),
the m-th part of the conductor film in the central portion is connected to the second extraction interconnect,
the first part of the conductor film in the peripheral portion is connected to the first extraction interconnect,
the i-th part of the second-conductivity-type region in the peripheral portion is connected to the (i+1)-th part of the conductor film in the peripheral portion, where i is an integer of 1 to (n−1), and
the n-th part of the second-conductivity-type region in the peripheral portion is connected to the second extraction interconnect.

17. The device according to claim 16, wherein
the base film and the piezoelectric film have a circular shape larger than the second-conductivity-type region, and
the parts of the second-conductivity-type region and the parts of the conductor film in the central portion are respectively placed at m-fold symmetric positions with respect to the center of the base film, and the parts of the second-conductivity-type region and the parts of the conductor film in the peripheral portion are respectively placed at n-fold symmetric positions with respect to the center of the base film.

18. The device according to claim 3, wherein
the device is a microphone, and
the second-conductivity-type region, the piezoelectric film, and the conductor film constitute a piezoelectric element, which is a sensing element configured to sense deformation of the base film.

19. The device according to claim 3, wherein
the device is an angular velocity sensor,
the second-conductivity-type region, the piezoelectric film, and the conductor film constitute piezoelectric elements,
one of the piezoelectric elements is a sensing element configured to sense deformation of the base film,
and another of the piezoelectric elements is a driving element configured to vibrate the base film.

20. The device according to claim 1, wherein the piezoelectric film is aluminum nitride film.
